(19) United States
(12) Patent Application Publication
(10) Pub. No.: US 2026/0300593 A1
(43) Pub. Date: Oct. 1, 2026

(54) CONCURRENT TESTING FOR SEMICONDUCTOR DEVICES

(71) Applicant: Intel Corporation, Santa Clara, CA (US)

(72) Inventors: Edward BRAZIL, Naas (IE); Baruch SCHNARCH, Zichron Yaakov (IL); Naphtali G. LEVY, Haifa (IL); Ahmad HAMDAN, Isfiya Village (IL)

(21) Appl. No.: 19/094,714

(22) Filed: Mar. 28, 2025

(51) Int. Cl. G06F 30/333

(52) U.S. Cl. CPC G06F 30/333

(57) ABSTRACT

Methods and systems are provided for bundling semiconductor tests. Bundling semiconductor tests can maximize test concurrency and minimize test time. Bundling of semiconductor tests includes breaking tests into parts and algorithms that are capable of interleaving the parts according to rules and constraints. Machine learning can be applied to predict run times for large numbers of bundle permutations.

### FIELD

Descriptions are generally related to semiconductor manufacturing, and more particular descriptions are related to testing semiconductor devices.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, precision and scaling requirements, power delivery requirements, limited failure tolerance, and material and manufacturing costs.

Device testing is a vital part of the semiconductor manufacturing process and especially high volume manufacturing (HVM) processes. Semiconductor chips typically contain design for test (DFT) features. Wafer, sort, and final test times have increased with increased chip device integration and increased transistor density. Decreasing these test times presents a complex problem.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIG. 1 illustrates semiconductor test patterns that are broken into constituent parts and interleaved.

FIG. 2 shows semiconductor test program pattern list examples.

FIG. 3 shows critical resources modeled as lanes in which semiconductor test pattern constituent parts are placed.

FIG. 4 demonstrates the effect of an aspect of a scheduling algorithm that incrementally increases schedule gap sizes to allow ordering of test pattern content from a plurality of test patterns.

FIG. 5 diagrams a system for a semiconductor test bundle permutation optimizer.

FIG. 6 shows a concurrent search process that includes minimum supply voltage (Vmin) searching.

FIG. 7 provides a method for bundling semiconductor test patterns.

FIG. 8 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as by physical operations. Operations can be performed by semiconductor processing and/or testing equipment, including computer systems that run testing protocols and operate aspects of testing equipment and systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry. Other components can be semiconductor processing and/or testing equipment that is able to perform physical operations such as, for example, robotically placing semiconductor chips into testing equipment.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed in part from semiconductor materials.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-κ dielectrics, SiO₂, silicon nitride (SiN), silicon carbide (SiC), and/or silicon carbonitride (SiCN). Low-κ dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric layers that include conductive features can be interlayer dielectric (ILD) features. In general, low-κ dielectrics exhibit a dielectric constant that is less than that of SiO₂.

The terms “package,” “packaging,” “IC package,” or “chip package,” “microelectronics package,” or “semiconductor chip package” are interchangeable and generally refer to an enclosed carrier of one or more chips, in which the chips are coupled to a package substrate and encapsulated. The package substrate provides electrical interconnections between the chip(s) and other chips and/or a motherboard or other circuit board for IO (input/output) communication and power delivery. A package with multiple chips can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

Test patterns provide procedures and tests used to verify semiconductor chip functionality, performance, and reliability. Test patterns include functional tests, structural tests, parametric tests, and reliability tests. Functional tests verify that a semiconductor chip preforms intended functions by simulating real-world computational and input/output (IO) scenarios. Structural tests are designed to detect manufacturing defects in a semiconductor chip's physical structure. Parametric tests are designed to measure and/or verify electrical parameters, such as voltage, current, and speed. Reliability tests assess the semiconductor chip's ability to withstand environmental stresses (e.g., temperature cycling, humidity, and vibration) and maintain performance levels over time.

Test programs (TPs) for semiconductor chips typically are developed and executed in a serial fashion. For example, first, the memory arrays are tested across a semiconductor device (such as a system-on a chip (SOC)), followed by logic tests, and then input/output (IO) tests. Within each TP sub-flow, the main heterogeneous (hetero) logic blocks and resources are also typically tested serially. From an SOC level view, serial testing can result in significant underutilization of the design-for test (DFT) fabric bandwidth. Each test pattern selected can have idle time during which the test is running internally on a logic block, and does not interact with the tester. This idle time can range from 30-99% of the overall pattern test time. Moreover, testing hetero logic blocks serially results in the additional overhead of repeated SOC power up and reset sequences. During each test segment, the remainder of the SOC is essentially idle, leaving valuable test fabric idle.

Concurrent testing of heterogenous logic blocks in a semiconductor device can be foundational to reducing the high-volume manufacturing (HVM) test times and manufacturing costs. The challenge of analyzing, segmenting, and scheduling hetero concurrent test content presents challenges for complex semiconductor devices. Shorter test times enabled by concurrent testing can directly translate into significant manufacturing cost savings, for products such as, for example, mainstream client and server processors.

Concurrent testing methodologies can include several parts, such as, for example, a concurrent test scheduler, an assistive bundle permutation optimizer, and components that allow concurrent test bundles on automated test equipment (ATE). Semiconductor device testing includes: a) voltage control per hetero logic block, b) test port(s), and c) device under test (DUT) clock connectivity. Different elements of the software testing technology include a) a tool that identifies split points and marks them in the pattern, b) a tool that measures the expected runtime of the parts, c) a tool that calculates the expected power/thermal draw for each part, d) a tool that schedules the parts optimally both time wise and power wise, e) a tool that uses machine learning to select and group the best mixes of content, and f) a tool that generates the best Vmin search in concurrency. Configurations describing all the constraints, and ways to describe them are also included.

A test pattern can be a sequence of inputs and expected outputs used to verify functionality and identify manufacturing defects. Test patterns interact with various parts of a semiconductor chip to probe and measure operation of the parts. Recyclable logic block test patterns which are re-playable serially on the ATE can be used. Test patterns include array built in self-test (BIST), scan automatic test pattern generation (ATPG), and functional test (FT) patterns for each logic block. Each test pattern can be analyzed and split into according to operations. Test patterns can consist of three primary constituent parts, which can have variable lengths: 1) the program sequence: instructions that configure the test mode, activate the DFT feature and launch the test, 2) the run: typically variable cycle clock counts of wait until the test completion, and 3) the check—instructions which read the result and compare pass/fail for the test pattern. Test types are typically one of the following: Array, Scan, Functional, or Analog/IO. The concurrent scheduling methodologies can work for these types of tests and others as well. The methodologies are not limited to a particular type of test or the tests described herein as examples.

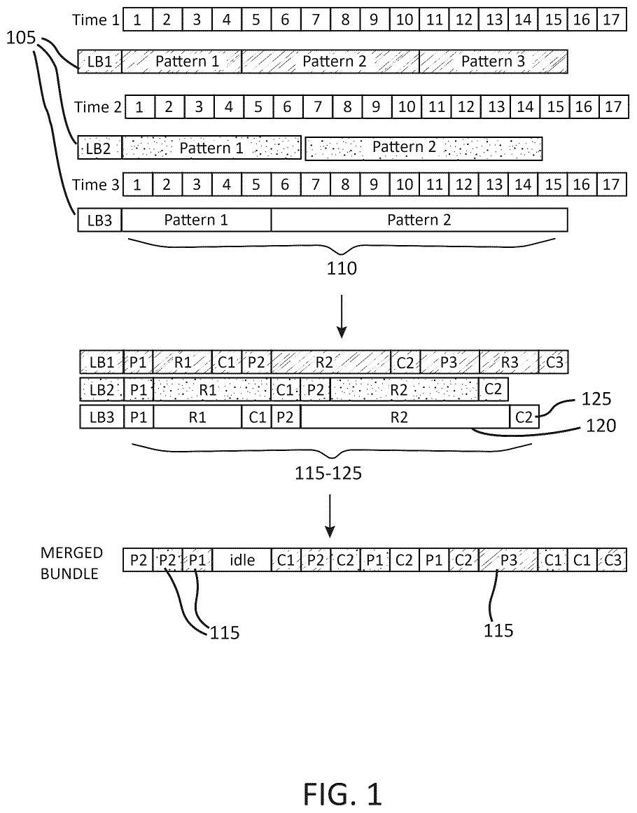

FIG. 1 illustrates a process for dividing semiconductor device tests (or test patterns) into test content parts (constituent parts). The content parts can be components of the test that represent program, run, and/or check parts of the test program's operation. The ATE can be idle during the time a test is running on a semiconductor device under test (DUT). Different content parts from different tests can be interleaved. By interleaving different content parts from different tests, overall test time (TT) for a DUT can be reduced. In FIG. 1, a simple example is shown (an actual test flow for a DUT is more complicated), in which three different logic blocks 105 (LB1, LB2, and LB3) are tested with two or three test patterns 110 each (LB1: 3 test patterns, LB2 and LB3: 2 test patterns). The test patterns 110 (Pattern 1, Pattern 2, and Pattern3) are divided into test program content parts: Program 115 (P1, P2, and P3), Run 120 (R1, R2, and R3), and Check 125 (C1, C2, and C3). The test program content parts can be reordered and interleaved to reduce the overall test time while maintaining test content rules and constraints. For example, a rule/constraint can be that the test pattern's wait time (i.e., idle time) should be equal to or longer than the original run time.

In the example of FIG. 1, three test patterns that are run in a serial manner can exhibit a total test run time of 42 (15 plus 13 plus 14). With the merged pattern list (merged bundle), the total test time has been reduced to 17. In this example, a time interval is marked as “idle,” indicating this is a non-optimized or wasted period of time. Program 115 and check 125 times can be considered busy times, since the ATE is interacting with the tested regions of the DUT, and the run 120 times can be considered idle times. In the example of FIG. 1, the test patterns 110 are divided into three constituent content parts 115, 120, and 125, however the test patterns 110 can also be divided into multiple program, run, and check parts. Further division of the constituent content parts (program, run and check) can allow additional reductions in overall semiconductor device test times.

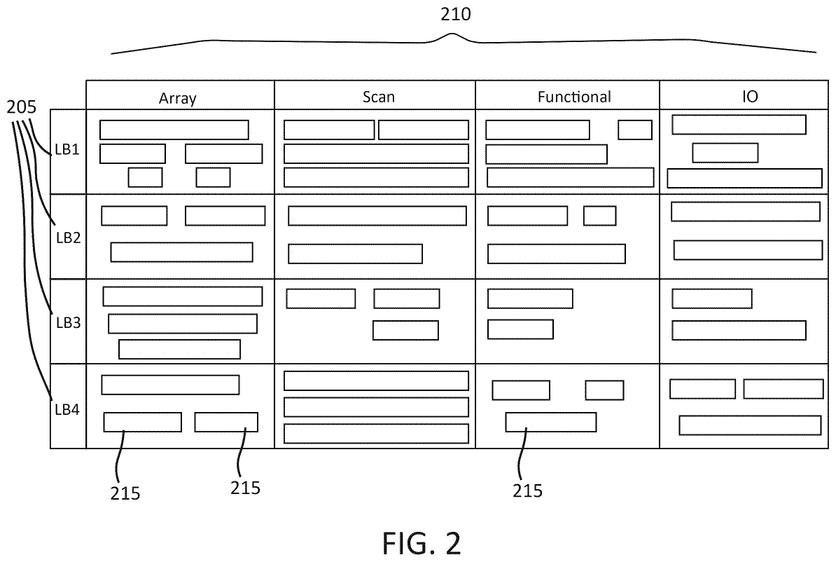

A typical testing program can contain hundreds of pattern lists and selecting the best pattern lists for each concurrent bundle from a large dataset can present challenges that can impact the time savings obtained. FIG. 2 shows a simplified example of a test program pattern list 210 by length, type, and frequency across different logic blocks 205 (LB1, LB2, LB3, and LB4). The size of the boxes indicates run times. These test patterns 215 shown as being executed serially. The test time of pattern lists for DUTS, in general, can vary greatly, due to the semiconductor tests having different numbers of patterns and different running frequencies. Selecting the best organization of pattern component lists into concurrent bundles is a complicated task and typically there are millions of options to select from. For a simplified example of one logic block pattern component list that has a test time of 800 ms that is run concurrently with one that has 100 ms: the maximum possible savings would be 100 ms. On the other hand, having two logic blocks each with 800 ms run time may or may not bring savings as the savings depend on the overall run time of the patterns, so that anywhere between 800 ms to 0 ms might be saved. The overall concurrent test time is impacted by the content type, and the number and size of the test program constituent parts.

Semiconductor device testing in parallel can be modeled as a job shop problem that is a known “NP-hard” problem. For a NP-hard problem, no optimal solution can be computed in deterministic polynomial time (NP being non-deterministic polynomial time). Allowing some assumptions and concessions, a solution can be obtained that is close to a theoretical limit. In polynomial time, if the assumptions and concessions are made, then the problem can become easier to solve, and no longer behaves as an NP-Hard problem and becomes “P” (=polynomial and deterministic. The solution may not be one that can be proven to be the best, but it can provide substantial gains in productivity. To achieve optimized semiconductor test scheduling, a solution is modeled after the rocks, pebbles, and sand problem solution in which more material can be placed into a jar of rocks and pebbles are inserted before the sand, versus the scenario where sand is placed first. The rocks, pebbles, and sand problem solution demonstrates that prioritizing between the types of tasks can allow fitting more tasks into the same time window.

Following the rocks, pebbles, and sand analogy, the semiconductor device test scheduler has two phases: first scheduling the rocks (larger test program content parts) using a heavy and complex algorithm and then adding the sand (smaller test program content parts) to the schedule via a lighter algorithm. The two phases are different scheduling algorithms that are used in combination in a two phase manner. The larger parts (“rocks”) algorithm is usually used for content types that are not uniform in part size and mostly comprise cases where the original content is broken down into large parts. The constituent parts of a semiconductor test need to maintain their order, and having many parts with this constraint can put a large and possibly unnecessary strain on the semiconductor device test scheduler. Content types with a large amount of uniformly small parts are modeled as sand in the semiconductor device test scheduler. The size of small and large parts is about relative scale and can vary from case to case depending on the given content. In some instances, rocks are at least an order of magnitude larger than the ‘small’ parts. The small parts can be broken down more or less depending on the desired level of granularity.

Test content parts can be modeled as an interval which is comprised of the starting point and length of the interval. The busy test content part intervals can be considered rigid, meaning that the only variable that can change is the starting point. The idle test content part intervals can be allowed to increase their size but not decrease it. The test content part intervals for parts that originated from each single test are then linked together by requiring that all start points maintain the correct (original) order. This merge between inflexible and flexible test content part intervals creates an image of rocks (busy parts) connected by flexible springs (idle parts).

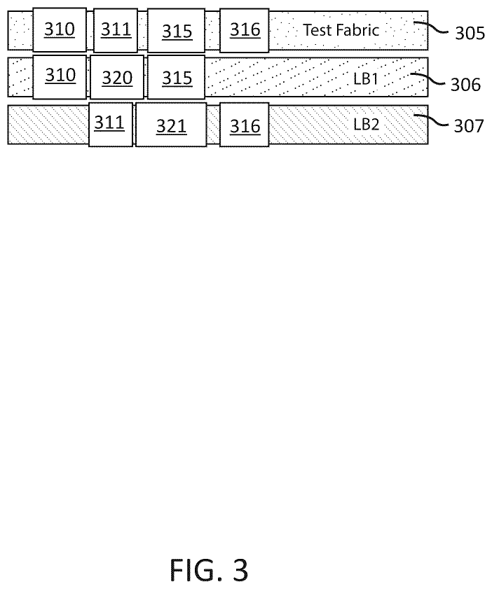

Each critical resource (e.g., test fabric or logic block) can be modeled as a “lane” in which test content part intervals can be placed and cannot overlap. The test content part intervals can take up more than one lane if the test content part consumes more than one critical resource. For example, busy intervals always take up both the test fabric and the logic block that is being tested. In FIG. 3, critical resources are modeled as lanes 305, 306, and 307 in which lane 305 is a test fabric, and lanes 306 and 307 are a first and a second logic block. Two different test patterns are run on logic block 306 and logic block 307, with both test patterns requiring the test fabric during the busy (program 310 and 311 and check 315 and 316) parts. The two test patterns include program 310 and 311, run 320 and 321, and check 315 and 316 constituent parts. The test patterns can be modeled with the idle (run 320 and 321) parts as variable (expanding) intervals between the busy intervals. By modeling the idle parts of the test patterns as variable, other parts of the same resource can be prevented from using the same critical resource between the busy/idle sections of a test pattern. If other constituent parts of the same resource use the same critical resource between the busy/idle sections of a test pattern results can be invalid.

Additional constraints can be added, such as, giving priority to certain constituent parts of a test pattern within a specific lane. Priority constraints can be modeled as a requirement that all constituent test pattern parts from a selected priority group have starting points that are smaller than (earlier than) the other constituent test pattern parts in a specific lane. It is also possible to prioritize an entire lane over another, regardless of which constituent test pattern parts use the lane. Prioritizing a lane is helpful, for example, to release a specific critical resource at an earlier time point, or if there is contention between lanes that it would be useful to resolve.

A concurrent test builder can consist of a first scheduling algorithm and a second scheduling algorithm. A first scheduling algorithm can be used to schedule the larger test pattern content parts (the rocks). This first scheduling algorithm typically is more complicated than the second scheduling algorithm that is used to schedule the smaller test content parts (the sand). A first scheduling of test pattern constituent parts can be accomplished, for example, using a variant of the JSP algorithm (Job Shop Problem algorithm), that describes a theoretical job shop with multiple machines and employees who must complete jobs in the minimum overall amount of time. The critical resources are, for example, sections of the chip that cannot run more than one test concurrently, and the test fabric which is driven by the tester itself. The JSP algorithm is a type of constraint satisfaction problem (CSP), and it is open-ended and allows adding additional constraints, such as, for example, ordering, costs, variable penalties, run time wait times, semiconductor device thermal budgets, semiconductor device power budgets, cooling/heating times due to variance in the thermals of tests, aggressor content which is impacting other tests, and tests which use multiple logic blocks. For run wait times, the test pattern's wait time should be equal to or longer than the original run time. A scheduler maintains that it still effectively has at least the same idle/wait time (though now something else will be run in that window) as before. The idle/wait time can be longer, though.

A second scheduling algorithm can be used to schedule the smaller test program content parts. The second scheduling can be done, for example, via an iterative eager algorithm which tries placing smaller test program content parts in the schedule gaps left by the first scheduling algorithm. An effective use case for the second scheduling algorithm is where the content to be scheduled is a large set of uniformly small busy parts. The second scheduling algorithm can be simpler than the first scheduling algorithm. The second scheduling algorithm can include constraints such as critical resource limitations and correct ordering. In some examples, the second scheduling algorithm only takes into account critical resource limitations and correct ordering.

The second scheduling algorithm can be run multiple times, each time using an increased allowance for gap sizes to allow fitting in the smaller test program content parts which are bigger than the found gaps. By increasing the allowed gap sizes in iterative actions, the second scheduling algorithm can determine the optimal point at which all the smaller test program content is placed within the gaps while minimizing the impact on the overall runtime of the entire test pattern sequence (concurrent bundle).

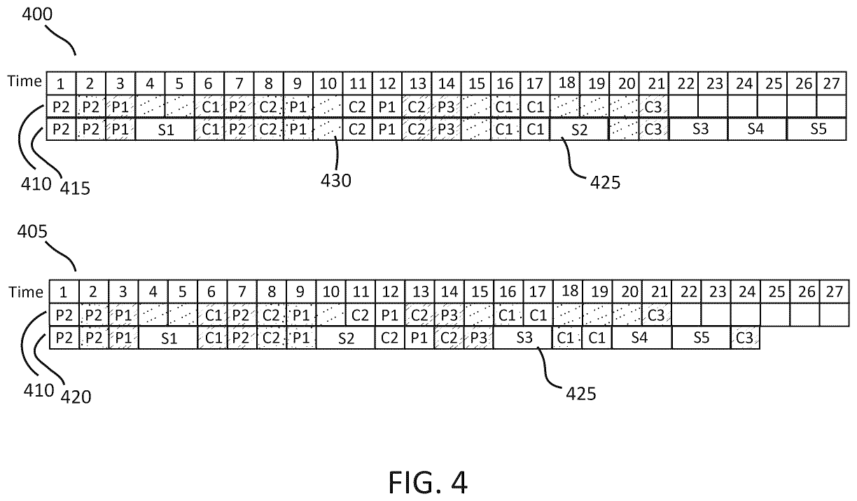

FIG. 4 shows the effect of iteratively and incrementally increasing gap size according to the second scheduling algorithm versus not increasing gap size, on overall run time for a semiconductor device testing concurrent bundle. After running the first scheduling algorithm, there are few idle time slots 430 in the results of the first algorithm 410. In the first concurrent bundle creation example 400 in which the second algorithm places the smaller test program content 425 (S1, S2, S3, S4, and S5) in available gaps from the results of the first algorithm 410, some smaller test program content 425 has been placed at the end of the concurrent bundle. Results of the second algorithm 415 can be compared with the results of the second algorithm with gap size modification 420. In the second concurrent bundle creation example 405 in which the second algorithm places the smaller test program content 425 (S1, S2, S3, S4, and S5) in gaps from the results of the first algorithm 410, where the gaps have been iteratively expanded to accommodate smaller test program content 410, it can be see that the total run time of the test concurrent bundle is decreased from 27 to 24. By iteratively expanding the gap size to accommodate smaller test program content 410, the overall test time for a semiconductor device can be decreased.

Power and thermal constraints can be modeled as reservoirs that may not exceed defined limits. Due to the differences between power and thermal, they can be modeled with slight variations. For example, power (maximum current) can be modeled as a reservoir per power rail, to which a test pattern part's power draw is added as a step function at the start of an interval and subtracted from at the end of the interval. Each test pattern part can optionally use more than one power rail, and its placement in the scheduling can be set to satisfy the hard limit of all the power rail reservoirs. Thermal (maximum temperature) can be modeled as a leaky bucket reservoir which is shared by all power domains, in which the thermal energy generated by each test pattern part is added gradually to the reservoir in proportion to the power requirement of that interval. The thermal reservoir is a leaky bucket in the sense that it decreases over time at a semi-fixed rate set by the concurrent bundle environment. The concurrent bundle environment can be one that models the thermal solution for the DUT. The thermal threshold can be established based on the product test specifications, and can be, for example, a value such as 100° C. ±15° C. The value can be derived from the chip power and the heat dissipation capacity. This difference between power and thermal modeling can prevent running high-power tests consecutively if only the current is tracked, because this can cause thermal runaway by overheating the chip before the thermal solution can dissipate the generated heat.

Semiconductor test concurrent bundles can be balanced between different resources, making efficient use of the test fabric (i.e., leaving low idle time for the test fabric), and refraining from creating significant bottlenecks which reduce total test time. A challenge in crafting such bundles is that there is content that can have different constraints and limitations, making balancing and construction difficult, and ongoing maintenance even more so. Changes that can be made to a test program after test concurrent bundles have been created may reduce the overall test concurrent bundle run time, and/or invalidate certain test concurrent bundles. These changes can require a reshuffling of the concurrent bundles.

The bundle permutation optimizer can generate possible permutations of semiconductor test concurrent bundles, under the provided rules and constraints. These permutations can be evaluated by either running them through the concurrent test builder (if the number of permutations is small) or predicting their value via machine learning (ML) (for large-scale problems). A reduced test time when run concurrently (relative to running it serial) is the ‘value’ of a selected bundle. If a bundle does not reduce any time, its value is 0. If a bundle increases time, the value is negative, meaning it would have been better to simply run the content serially.

These permutations can be provided to the bundle permutation solver, which can be a form of a Knapsack solver. The bundle permutation optimizer returns the best combination of concurrent bundles with the best test time reduction and prevents overlap of test pattern content between the selected permutations of test concurrent bundles. Multiple test content concurrent bundles can be created. There can be multiple ‘sets’ of bundles which are exclusive to each other (meaning, they are different mixes of same content). Many permutations and bundles are generated and best ones (multiples) out of those permutations are selected.

The bundle permutation optimizer can select from the given permutations and any invalid permutations can be removed from the selection input. Once the training of the ML models has yielded desired results, the trained models can be saved. The user can provide the bundle permutation optimizer with the test pattern part lists to be considered for concurrent bundles (i.e., a test pattern part lists inventory) along with a set of rules and constraints to indicate what type of concurrent bundles and content mixes are allowed. The permutation builder can create allowed test concurrent bundles to be evaluated. The ML prediction can use test bundle permutations along with their content information (e.g., content-type, time, and busy %) to predict the concurrent test builder results. The Knapsack Solver then takes those projected results and provides the best set of concurrent bundles which bring the best overall test time while using all the test pattern part lists inventory components. Note that the bundle permutation optimizer may end up having test pattern part lists inventory components without a good match for a bundle. Test patterns that are not a match for a bundle can be considered one-level bundles and be run serially. The bundle permutation optimizer can consider the various constraints between the different test patterns and select time optimized permutations of all possible semiconductor test bundles.

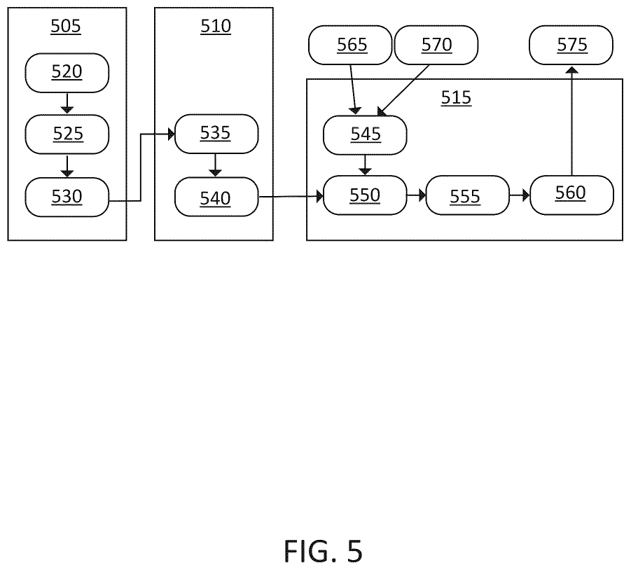

FIG. 5 diagrams a system for reducing semiconductor device testing time. The system of FIG. 5 can be a bundle permutation optimizer. The system includes a data training module 505, model building module 510, and a bundle permutation solver 515. Data training module 505 includes bundle specifications 520, permutations builder 525 and scheduler runs 530. Bundle specifications can be written by a user and can contain information about: a) Which patterns to include in the bundle (these are usually lists/groups of patterns), b) Any special rules or constraints between the different pattern groups, c) General schedule/bundle configurations (e.g., Thermal and power limits, max number of parallel resources, and how long the scheduler should run). The permutation builder can generate new permutated bundle specifications by taking existing user written bundle specifications and building off of them (mixing/splicing as needed).

The model building module 510 includes a module building unit 535 and a dataset of trained modules 540. The permutation builder generates all possible valid bundle permutation sets with the given rules and limitations. It provides a list of all the possible permutations, their bundle specifications, and any additional information describing what that bundle is. The schedule can take those permutations and perform a real concurrent build of that bundle. It takes each permutation and run it through the scheduler to get a result.

The model building module 535 takes data from the scheduler runs 530 output. The trained modules 540 are input into the ML prediction unit 550 of the permutation solver 515. The permutation solver 515 also includes a permutations builder 545 and a knapsack solver 560. The output of the ML prediction unit 550, the projected results 555, are input into the knapsack solver 560 which outputs optimized test bundle specifications 575. The test pattern parts inventory 565 and the bundle rules 570 are input into the permutations builder 545. The permutations builder 545 provides permutation information to the ML prediction unit 550.

The knapsack algorithm (e.g., the knapsack solver 560) used in the bundle permutation optimizer can be a variant of the 0-1 multi-dimensional knapsack problem in which each item may be taken at most once, and the items have a relationship between them other than just value. For the bundle permutation optimizer, the value of a test bundle is how much test time it saves where the test bundle comprised of the test pattern components used to construct the test bundle. Each test pattern component may be taken at most once (0-1) and has a relationship with the other test pattern components in the given bundle permutation, causing the problem to be multi-dimensional/multi-choice. The solver for the problem is a linear programming (LP) 1-0 Knapsack solver, in which the bundles and the test pattern components are described as a 2-dimensional matrix of 1s and 0s, each row being a bundle and the column whether a test pattern component was taken (marked as 1 when taken). The bundle values are defined by a matching vector of the same dimension. These are then provided to the solver, which returns the bundle mixes that satisfy the constraints and provide the best solution.

Constraining the bundle permutation optimizer can prevent creating test bundle mixes that do not make sense or are invalid due to, for example, design and/or functional limitations. The complexity of the bundle mixes can be constrained, so that test bundles do not become difficult to maintain and validate. In addition, it is important to constrain the number of possible generated permutations to a feasible order of magnitude, otherwise, it is possible to generate billions of possible permutations which are out of the scope of the bundle permutation optimizer. To achieve this, the bundle permutation optimizer permutation generator can limit how the test content part lists are allowed to be paired. It does this using ‘groups’ and ‘subgroups’ which are allowed or not allowed to be paired. In addition, it is possible to provide an ‘exclusion’ rule to disallow specific cases which are known to be problematic. Valid mixes from the above test content part lists can be limited to a subset of all possible bundles, selecting a limited number of critical resources and a limited amount of test content part lists when bundling a test bundle.

It can be important to determine the minimum supply voltage (Vmin) at which a semiconductor chip and/or the individual logic blocks within the semiconductor chip operate properly. Under-voltages or over-voltages can compromise the reliability of the semiconductor chip over time. Vmin searches can be executed serially per power domain using an efficient incremental search algorithm. The concurrent semiconductor tests can include a Vmin search solution—an algorithm and tester software solution which enables heterogeneous power rail searching with concurrent content. The Vmin search can work by finding the ideal point to jump back to, the problem of needing to roll back when a pattern fails is solved, though other patterns are already in flight. The collateral describes where these jump points are, and which power rails need to be ‘ticked’ due to the fail. This file is provided to the Test Program execution flow and is parsed by them when running on tester.

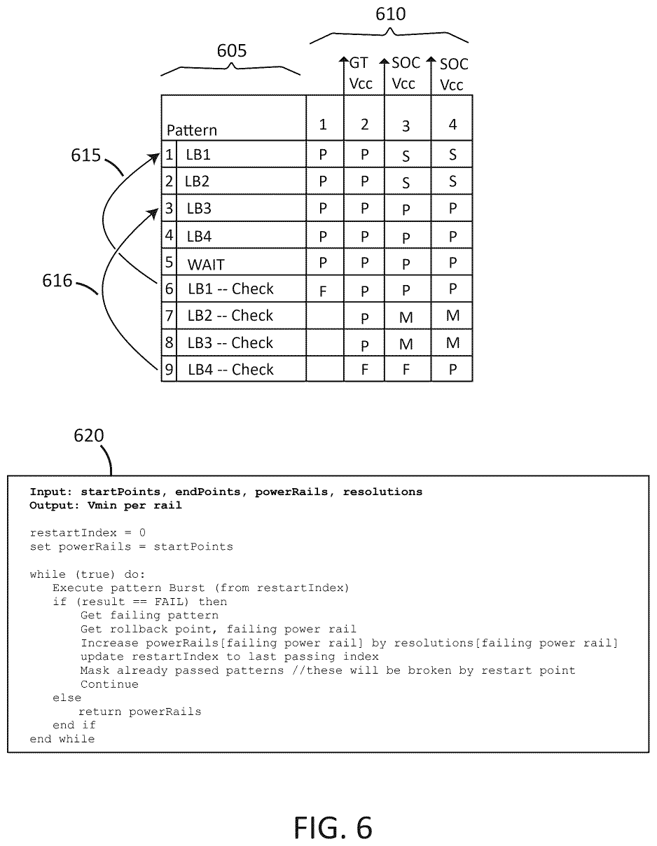

Due to the nature of concurrent power rail search, resuming a test with increased Vcc (voltage at the common collector) does not start from the last failing pattern and instead returns to an earlier point in the test content part list while considering patterns that can be skipped and patterns that must be masked. An example is illustrated in FIG. 6 which shows a 9-pattern semiconductor test part list 605 for logic blocks 1-9 (LB1-LB9), and four simulated search iterations 610. In action #1, when pattern #6 failed (F), the rollback 615 occurs at pattern #1 since the check parts failed to complete. In action #2 when pattern #9 failed, the rollback 616 occurs at pattern #3, and because patterns #1 and 2 were skipped(S), their check parts (patterns #7 and 8) are masked (M). Passing patterns are marked with a “P” in the grid. Minimum safe voltages are predetermined using serial searches of short basic DFT loopback tests, which can mitigate the risk of inter-rail dependency. The Vcc of each logic block is increased when a failure is encountered in one of the test patterns associated with that logic block. When a failure is encountered, the execution restarts the program segment of that logic block current test pattern. Box 620 provides an example of a concurrent search algorithm.

Automated test equipment (ATE) for semiconductor devices typically includes a computerized controller and one or more instruments, such as, for example digital signal processing (DSP) instruments that measure voltage, oscilloscopes, multimeters, signal generators, and power supplies. ATEs can interface with an automated placement tool, that places a DUT on an Interface Test Adapter (ITA) so that the DUT can be tested. The ATE interfaces with the ITA. The ATE can test whether the DUT is working correctly. The ATE may also be able to diagnose the reason a DUT has failed testing. The ATE can include software and/or algorithms for performing one or more of the functions described herein or can interface with a second computer system capable of performing one or more of the functions described herein. The ATE or a different computer system can store, for example, the trained modules 540. Modules 540 are groups of test bundles and the ATE loads the bundles in a test program.

An optimal test schedule can be determined algorithmically, and split test patterns can be generated which execute the tests concurrently on the semiconductor chip in minimal test time. Test power constraints can be satisfied during the scheduling, using power metrics for each test pattern operation. For example, if an SOC has a 10 A power budget for a specific power rail, the concurrent test content will be scheduled balancing the trade-off of test time and test power, keeping the power below 10 A in the shortest possible test time.

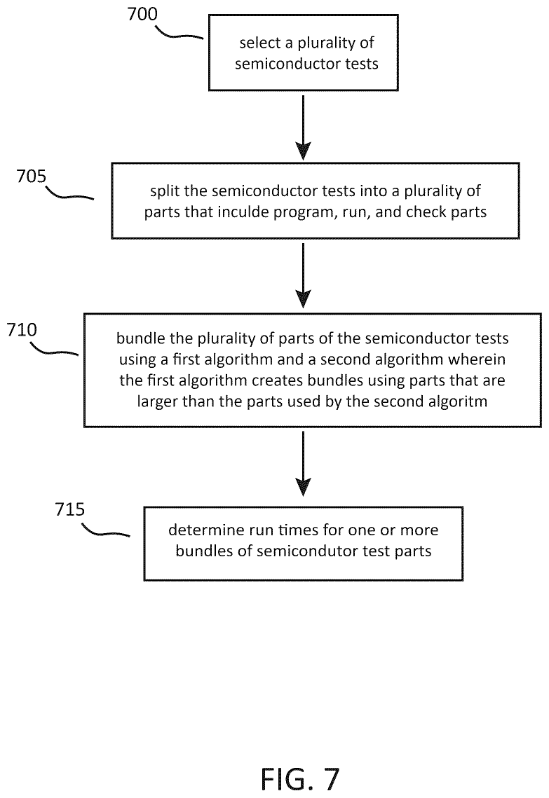

FIG. 7 provides a method for bundling semiconductor tests that can include any of the algorithms described herein. A plurality of semiconductor tests is selected for testing the logic blocks of a semiconductor chip 700. The semiconductor tests are split into a plurality of parts that at least include program, run, and check parts 705. The plurality of parts of the plurality of selected semiconductor tests are bundled using a first and a second algorithm 710. The first algorithm creates a first bundle using larger parts than are used by the second algorithm. The second algorithm takes the partially formed bundle and inserts additional parts into the bundle in gaps in the bundle. The second algorithm can be run a second time and the sizes of the remaining gaps increased to accommodate parts that were not interleaved in the first run of the second algorithm. This can be repeated. Run times are determined for the one or more bundles that are created 715. Machine learning can be used to predict bundle run times for large numbers of bundles. The bundles that are created can have shorter run times than the constituent tests run in a serial manner. The creation of the bundles can occur according to rules and/or constraints.

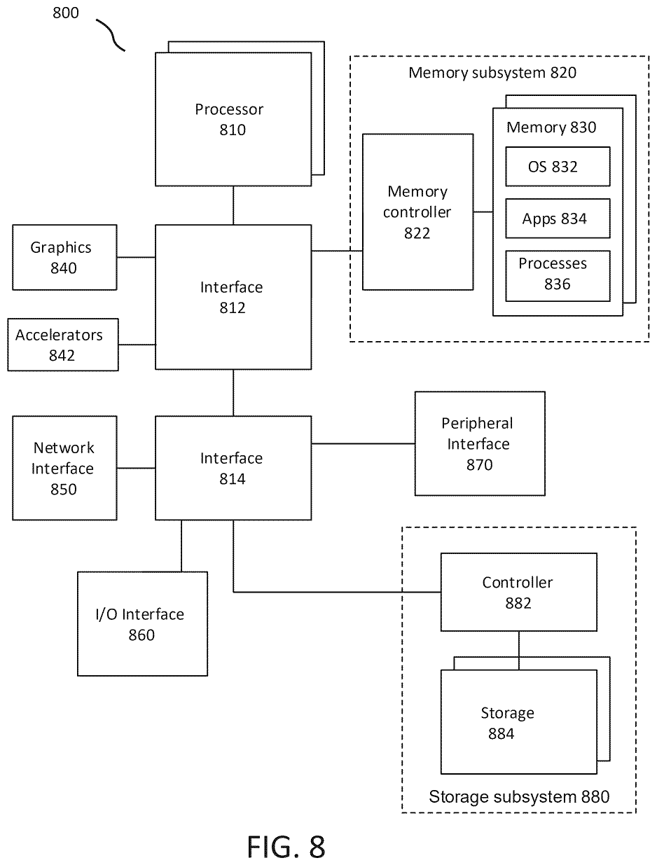

Semiconductor devices (or chips) can be any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, IO management, programmable controllers, ASICs, programmable logic devices (PLDs), HBM, and/or other memory devices. These semiconductor chip packages can be heterogeneous packages that incorporate different types of chips into one package. The semiconductor chips can be any of the chips, for example, described herein with respect to FIG. 8. The semiconductor chip packages described herein generally can be part of various larger package structures and configurations and the foregoing examples are not meant to limit the types of assemblies that are possible.

FIG. 8 depicts an example computing system. The computing system can be used for creating bundles of semiconductor test patterns and predicting total test times for the bundles of semiconductor test patterns and can be part of an ATE. For example, instructions for operating an ATE and/or for performing one or more aspects of the methods described herein can be stored and/or run on the computing system. A computing system 800 can include more, different, or fewer features than the ones described with respect to FIG. 8.

Computing system 800 includes processor 810, which provides processing, operation management, and execution of instructions for system 800. Processor 810 can include any type of microprocessor, CPU (central processing unit), GPU (graphics processing unit), processing core, or other processing hardware to provide processing for system 800, or a combination of processors or processing cores. Processor 810 controls the overall operation of system 800, and can be or include, one or more programmable general-purpose or special-purpose microprocessors, DSPs, programmable controllers, ASICs, programmable logic devices (PLDs), or the like, or a combination of such devices.

In one example, system 800 includes interface 812 coupled to processor 810, which can represent a higher speed interface or a high throughput interface for system components needing higher bandwidth connections, such as memory subsystem 820 or graphics interface components 840, and/or accelerators 842. Interface 812 represents an interface circuit, which can be a standalone component or integrated onto a processor die. Where present, graphics interface 840 interfaces to graphics components for providing a visual display to a user of system 800. In one example, the display can include a touchscreen display.

Accelerators 842 can be a fixed function or programmable offload engine that can be accessed or used by a processor 810. For example, an accelerator among accelerators 842 can provide data compression (DC) capability, cryptography services such as public key encryption (PKE), cipher, hash/authentication capabilities, decryption, or other capabilities or services. In some cases, accelerators 842 can be integrated into a CPU socket (e.g., a connector to a motherboard (or circuit board, printed circuit board, mainboard, system board, or logic board) that includes a CPU and provides an electrical interface with the CPU). For example, accelerators 842 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 842 can provide multiple neural networks, CPUs, processor cores, general purpose graphics processing units, or graphics processing units can be made available for use by artificial intelligence (AI) or machine learning (ML) models.

Memory subsystem 820 represents the main memory of system 800 and provides storage for code to be executed by processor 810, or data values to be used in executing a routine. Memory subsystem 820 can include one or more memory devices 830 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 830 stores and hosts, among other things, operating system (OS) 832 that provides a software platform for execution of instructions in system 800, and stores and hosts applications 834 and processes 836. In one example, memory subsystem 820 includes memory controller 822, which is a memory controller to generate and issue commands to memory 830. The memory controller 822 can be a physical part of processor 810 or a physical part of interface 812. For example, memory controller 822 can be an integrated memory controller, integrated onto a circuit within processor 810.

System 800 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 800 includes interface 814, which can be coupled to interface 812. In one example, interface 814 represents an interface circuit, which can include standalone components and integrated circuitry. In one example, user interface components or peripheral components, or both, couple to interface 814. Network interface 850 provides system 800 the ability to communicate with remote devices (e.g., servers or other computing devices) over one or more networks. Network interface 850 can include an Ethernet adapter, wireless interconnection components, cellular network interconnection components, USB, or other wired or wireless standards-based or proprietary interfaces. Network interface 850 can transmit data to a device that is in the same data center or rack or a remote device, which can include sending data stored in memory.

Some examples of network interface 850 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 800 includes one or more input/output (IO) interface(s) 860. IO interface 860 can include one or more interface components through which a user interacts with system 800 (e.g., audio, alphanumeric, tactile/touch, or other interfacing). Peripheral interface 870 can include additional types of hardware interfaces, such as, for example, interfaces to semiconductor fabrication equipment and/or electrostatic charge management devices.

In one example, system 800 includes storage subsystem 880. Storage subsystem 880 includes storage device(s) 884, which can be or include any conventional medium for storing data in a nonvolatile manner, such as one or more magnetic, solid state, and/or optical based disks. Storage 884 can be generically considered to be a “memory,” although memory 830 is typically the executing or operating memory to provide instructions to processor 810. Whereas storage 884 is nonvolatile, memory 830 can include volatile memory (e.g., the value or state of the data is indeterminate if power is interrupted to system 800). In one example, storage subsystem 880 includes controller 882 to interface with storage 884. In one example controller 882 is a physical part of interface 812 or processor 810 or can include circuits or logic in both processor 810 and interface 814.

A power source (not depicted) provides power to the components of system 800. More specifically, power source typically interfaces to one or multiple power supplies in system 800 to provide power to the components of system 800.

Examples of systems may be implemented in various types of computing, smart phones, tablets, personal computers, and networking equipment, such as switches, routers, racks, and blade servers such as those employed in a data center and/or server farm environment.

A system can comprise: a computer system wherein the computer system comprises instructions that cause the computer system to: create permutations of concurrent bundles of semiconductor test patterns wherein the concurrent bundles of semiconductor test patterns are comprised of at least two semiconductor test patterns wherein the at least two semiconductor test patterns are each broken into at least three constituent parts, predict a total test run time for each of the permutations of concurrent bundles based on content type of the at least three constituent parts of each of the at least two semiconductor test patterns; and select one or more concurrent bundles of semiconductor test patterns wherein a selected concurrent bundle of semiconductor test patterns exhibits a lower total run time than a sum of total run times of individual semiconductor test patterns of the at least two semiconductor test patterns; and a first interface capable of interfacing with a second interface that is capable of coupling to a semiconductor chip wherein the computer system is capable of sending and receiving data from a semiconductor chip coupled to the second interface through the first interface. The at least three constituent parts can comprise a program part, a run part, and a check part and wherein the run part is considered an idle part. Creating permutations of concurrent bundles of semiconductor test patterns can include creating permutations of concurrent bundles of semiconductor subject to constraints. The constraints can include ordering of the at least three constituent parts and a thermal budget for the semiconductor chip. The semiconductor test patterns can be semiconductor test patterns that contain idle time. The semiconductor test patterns can include array built in self-test (BIST), scan automatic test pattern generation (ATPG), and functional test (FT) patterns, and input/output (IO) tests. The instructions can also include concurrent minimum supply voltage (Vmin) searching for the semiconductor chip.

A method can comprise: splitting two or more semiconductor tests into parts wherein the parts comprise at least a program part, a run part, and a check part for each of the two or more semiconductor tests; bundling a plurality of parts according to constraints using a first algorithm and a second algorithm, wherein the first algorithm orders a plurality of parts that are larger than the parts that are ordered by the second algorithm, wherein the second algorithm interleaves a plurality of parts into gaps left by the first algorithm; and determining a first run time for a bundle of parts of the plurality of parts wherein the first run time for the bundle of parts is less than a second run time that is a sum of part run times for the plurality of parts. The run part can be considered an idle part for testing resources that include automated testing equipment. The method can also include running the second algorithm a second time and increasing gap size for the gaps that were not filled during a first run of the second algorithm. The bundles of parts can be created subject to constraints and wherein the constraints include ordering of the parts. The constraints can also include a thermal budget for a semiconductor device to be tested. Bundling can also include prioritizing parts. The semiconductor tests can include array built in self-test (BIST), scan automatic test pattern generation (ATPG), functional test (FT) tests, and input/output (IO) tests.

At least one machine-readable storage medium can comprise non-transitory instructions, that when executed by a processor, cause a device to: split two or more semiconductor tests into parts wherein the parts comprise at least a program part, a run part, and a check part for each of the two or more semiconductor tests; bundle a plurality of tests according to constraints using a first algorithm and a second algorithm, wherein the first algorithm orders a plurality of parts that are larger than the parts that are ordered by the second algorithm, wherein the second algorithm interleaves a plurality of parts into gaps left by the first algorithm; and determine run times for each bundle of tests of the plurality of tests. The run part can be considered an idle part for testing resources that include automated testing equipment. The constraints can also include a thermal budget for a semiconductor device to be tested. The constraints can also include a thermal budget for a semiconductor device to be tested. The instructions can also include using predictive machine learning algorithms to determine bundle run times. The semiconductor tests can include array built in self-test (BIST), scan automatic test pattern generation (ATPG), functional test (FT) tests, and input/output (IO) tests.

Besides what is described herein, various modifications can be made to what is disclosed and implementations without departing from their scope. Therefore, the illustrations and examples herein should be construed in an illustrative, and not a restrictive sense.

What is claimed is:

1. A system comprising:
a computer system wherein the computer system comprises instructions that cause the computer system to:
create permutations of concurrent bundles of semiconductor test patterns wherein the concurrent bundles of semiconductor test patterns are comprised of at least two semiconductor test patterns wherein the at least two semiconductor test patterns are each broken into at least three constituent parts,
predict a total test run time for each of the permutations of concurrent bundles based on content type of the at least three constituent parts of each of the at least two semiconductor test patterns; and
select one or more concurrent bundles of semiconductor test patterns wherein a selected concurrent bundle of semiconductor test patterns exhibits a lower total run time than a sum of total run times of individual semiconductor test patterns of the at least two semiconductor test patterns; and
a first interface capable of interfacing with a second interface that is capable of coupling to a semiconductor chip wherein the computer system is capable of sending and receiving data from a semiconductor chip coupled to the second interface through the first interface.

2. The system of claim 1, wherein the at least three constituent parts comprise a program part, a run part, and a check part and wherein the run part is considered an idle part.

3. The system of claim 1 wherein creating permutations of concurrent bundles of semiconductor test patterns includes creating permutations of concurrent bundles of semiconductor subject to constraints.

4. The system of claim 3 wherein the constraints include ordering of the at least three constituent parts and a thermal budget for the semiconductor chip.

5. The system of claim 1 wherein the semiconductor test patterns are semiconductor test patterns that contain idle time.

6. The system of claim 1 wherein the semiconductor test patterns include array built in self-test (BIST), scan automatic test pattern generation (ATPG), and functional test (FT) patterns, and input/output (IO) tests.

7. The system of claim 1 wherein the instructions also include concurrent minimum supply voltage (Vmin) searching for the semiconductor chip.

8. A method comprising:
splitting two or more semiconductor tests into parts wherein the parts comprise at least a program part, a run part, and a check part for each of the two or more semiconductor tests;
bundling a plurality of parts according to constraints using a first algorithm and a second algorithm, wherein the first algorithm orders a plurality of parts that are larger than the parts that are ordered by the second algorithm, wherein the second algorithm interleaves a plurality of parts into gaps left by the first algorithm; and
determining a first run time for a bundle of parts of the plurality of parts wherein the first run time for the bundle of parts is less than a second run time that is a sum of part run times for the plurality of parts.

9. The method of claim 8 wherein the run part is considered an idle part for testing resources that include automated testing equipment.

10. The method of claim 8 also including running the second algorithm a second time and increasing gap size for the gaps that were not filled during a first run of the second algorithm.

11. The method of claim 8 wherein the bundles of parts are created subject to constraints and wherein the constraints include ordering of the parts.

12. The method of claim 8 wherein the constraints also include a thermal budget for a semiconductor device to be tested.

13. The method of claim 8 wherein bundling also includes prioritizing parts.

14. The method of claim 8 wherein the semiconductor tests include array built in self-test (BIST), scan automatic test pattern generation (ATPG), functional test (FT) tests, and input/output (IO) tests.

15. At least one machine-readable storage medium comprising non-transitory instructions, that when executed by a processor, cause a device to:
split two or more semiconductor tests into parts wherein the parts comprise at least a program part, a run part, and a check part for each of the two or more semiconductor tests;
bundle a plurality of semiconductor tests according to constraints using a first algorithm and a second algorithm, wherein the first algorithm orders a plurality of parts that are larger than the parts that are ordered by the second algorithm, wherein the second algorithm interleaves a plurality of parts into gaps left by the first algorithm; and
determine run times for each bundle of semiconductor tests of the plurality of semiconductor tests.

16. The at least one machine-readable storage medium of claim 15 the run part is considered an idle part for testing resources that include automated testing equipment.

17. The at least one machine-readable storage medium of claim 15 wherein the constraints also include a thermal budget for a semiconductor device to be tested.

18. The at least one machine-readable storage medium of claim 15 wherein the constraints also include a thermal budget for a semiconductor device to be tested.

19. The at least one machine-readable storage medium of claim 15 wherein the non-transitory instructions also include using predictive machine learning algorithms to determine bundle run times.

20. The at least one machine-readable storage medium of claim 15 wherein the semiconductor tests include array built in self-test (BIST), scan automatic test pattern generation (ATPG), functional test (FT) tests, and input/output (IO) tests.
